(19) United States
(12) Patent Application Publication
(10) Pub. No.: US 2023/0387862 A1
(43) Pub. Date: Nov. 30, 2023

(54) POWER AMPLIFICATION CIRCUIT

(71) Applicant: Murata Manufacturing Co., Ltd., Nagaokakyo-shi (JP)

(72) Inventors: Takeshi OSHIMA, Nagaokakyo-shi (JP); Kazuhiro UEDA, Nagaokakyo-shi (JP)

(73) Assignee: Murata Manufacturing Co., Ltd., Nagaokakyo-shi (JP)

(21) Appl. No.: 18/446,542

(22) Filed: Aug. 9, 2023

Related U.S. Application Data
(63) Continuation of application No. PCT/JP2022/004423, filed on Feb. 4, 2022.

(30) Foreign Application Priority Data
Feb. 12, 2021 (JP) 2021-021221

(51) Int. Cl. H03F 1/02; H03F 3/24; H03F 1/56

(52) U.S. Cl. CPC H03F 1/0288; H03F 3/245; H03F 1/565; H03F 2200/451

(57) ABSTRACT

A power amplification circuit performs power amplification appropriate for the condition of an input signal. The power amplification circuit includes a splitter that includes a variable inductance element and a variable capacitance element and that splits a signal into a signal having a first power level and a signal having a second power level based on a value of inductance of the variable inductance element and a value of capacitance of the variable capacitance element. A carrier amplifier is connected to the splitter and amplifies the signal and output a signal. A peaking amplifier is connected to the splitter and outputs a signal when the second power level is greater than or equal to a predetermined power level, and a combiner (combines the two signals from the respective amplifiers.

This application is a continuation of, and claims priority to, international application no. PCT/JP2022/004423, filed Feb. 4, 2022, and which claims priority to Japanese application no. JP 2021-021221, filed Feb. 12, 2021. The entire contents of both prior applications are hereby incorporated by reference.

### TECHNICAL FIELD

The present disclosure relates to a power amplification circuit.

### BACKGROUND ART

The Doherty amplifier is known as a power amplification circuit having high efficiency. In general, the Doherty amplifier has a configuration including a carrier amplifier and a peaking amplifier connected in parallel. In this configuration, the carrier amplifier is configured to operate regardless of the power level of an input signal, and the peaking amplifier is turned off when the power level of the input signal is low and turned on when the power level of the input signal is high. When the power level of the input signal is high, the carrier amplifier operates keeping a saturated output power level. The Doherty amplifier can provide higher efficiency than ordinary power amplification circuits.

As a modification to the Doherty amplifier, the Doherty amplifier can be configured to unevenly split an input signal. Such a Doherty amplifier is configured to supply signals having different levels one each to a carrier amplifier and a peaking amplifier and thereby efficiently combine the output signal from the carrier amplifier and the output signal from the peaking amplifier at a similar or the same level. Thus, high efficiency and linearity are obtained by using a simple configuration.

### CITATION LIST

### Patent Document

Patent Document 1: Japanese Unexamined Patent Application Publication No. 2006-339981

### SUMMARY OF INVENTION

### Technical Problem

Examples of an input signal provided to a power amplification circuit include signals having different power levels and signals having different frequencies. For appropriate amplification of an input signal, a power amplification circuit is required to perform amplification based on the peak to average power ratio (PAPR) of the input signal or perform amplification by switching between operational states such as a high power mode and a low power mode. As in the case of the Doherty amplifier described above, if an input signal is split based on a predetermined value of the split ratio, appropriate amplification is difficult to achieve by using a power amplifier based on the condition of the input signal, such as the power level or the frequency.

To address such issues, exemplary aspects of the present disclosure provide a power amplification circuit configured to perform power amplification appropriate for the condition of an input signal.

### Exemplary Solution to Problem

A power amplification circuit according to an aspect of the present disclosure includes a splitter that includes at least one variable inductance element and at least one variable capacitance element and that is configured to split a first signal into a second signal having a first power level and a third signal having a second power level based on a value of capacitance of each of the at least one variable capacitance element and a value of inductance of each of the at least one variable inductance element; a first amplifier that is connected to the splitter and that is configured to amplify the second signal and output a fourth signal; a second amplifier that is connected to the splitter and that is configured to amplify the third signal and output a fifth signal when the second power level is greater than or equal to a predetermined power level; and a combiner configured to combine the fourth signal and the fifth signal.

### Exemplary Advantageous Effects

The present disclosure can provide a power amplification circuit configured to perform power amplification appropriate for the condition of an input signal.

### BRIEF DESCRIPTION OF DRAWINGS

FIG. 1 is a circuit diagram of a power amplification circuit according to a first exemplary embodiment.

FIG. 2 is a circuit diagram of a variable inductance element according to the first exemplary embodiment.

FIG. 3 is a graph for describing the operation of the power amplification circuit according to the first exemplary embodiment.

FIG. 4 is a circuit diagram of a power amplification circuit according to a second exemplary embodiment.

FIG. 5 is a graph for describing the operation of the power amplification circuit according to the second exemplary embodiment.

FIG. 6 is a circuit diagram of a power amplification circuit according to a third exemplary embodiment.

FIG. 7 is a circuit diagram of a power amplification circuit according to a fourth exemplary embodiment.

FIG. 8 is a circuit diagram of a power amplification circuit according to a fifth exemplary embodiment.

### DETAILED DESCRIPTION OF EXEMPLARY EMBODIMENTS

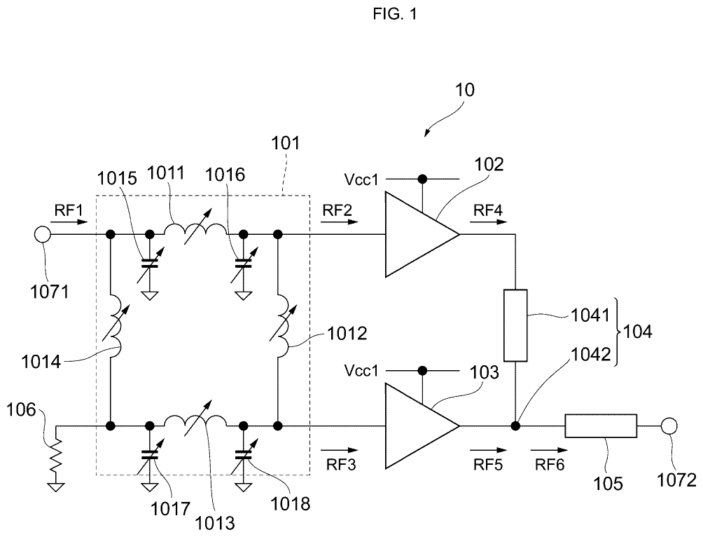

A first exemplary embodiment will be described herein. FIG. 1 is a circuit diagram of a power amplification circuit 10 according to the first exemplary embodiment. The power amplification circuit 10 includes a splitter 101, a carrier amplifier 102 (first amplifier), a peaking amplifier 103 (second amplifier), a combiner 104, a phase shifter 105, and a terminating resistor element 106.

The power amplification circuit 10 is a Doherty amplifier configured to perform power amplification based on the power level of a signal RF1 that is input to an input end 1071, and the power amplification is performed by using the carrier amplifier 102 or by using the carrier amplifier 102 and the peaking amplifier 103.

The splitter 101 is connected to the input end 1071, the carrier amplifier 102, the peaking amplifier 103, and the terminating resistor element 106. The splitter 101 is configured to split the signal RF1 (first signal) into a signal RF2 (second signal) and a signal RF3 (third signal), the signal RF1 being received by the splitter 101 after being input to the input end 1071. The signal RF2 is provided to the carrier amplifier 102, and the signal RF3 is provided to the peaking amplifier 103.

The splitter 101 includes variable inductance elements 1011, 1012, 1013, and 1014. The variable inductance elements 1011, 1012, 1013, and 1014 correspond to a first variable inductance element, a second variable inductance element, a third variable inductance element, and a fourth variable inductance element, respectively.

The splitter 101 includes variable capacitance elements 1015, 1016, 1017, and 1018. The variable capacitance elements 1015, 1016, 1017, and 1018 correspond to a first variable capacitance element, a second variable capacitance element, a third variable capacitance element, and a fourth variable capacitance element, respectively.

Each of the variable inductance elements 1011, 1012, 1013, and 1014 is a circuit element whose value of inductance can be varied based on an external control signal. The circuits of the variable inductance elements 1011, 1012, 1013, and 1014 will be described below.

Each of the variable capacitance elements 1015, 1016, 1017, and 1018 is a circuit element whose value of capacitance can be varied based on an external control signal. Examples of a device that can be used as the variable capacitance elements 1015, 1016, 1017, and 1018 include a variable capacitance diode and a digitally tunable capacitor (DTC).

The variable inductance element 1011 includes Terminal 1 (first terminal) connected to the input end 1071 and Terminal 2 (second terminal) connected to the input of the carrier amplifier 102.

The variable inductance element 1012 includes Terminal 1 (third terminal) connected to Terminal 2 of the variable inductance element 1011 and Terminal 2 (fourth terminal) connected to the input of the peaking amplifier 103.

The variable inductance element 1013 includes Terminal 1 (fifth terminal) grounded via the terminating resistor element 106 and Terminal 2 (sixth terminal) connected to Terminal 2 of the variable inductance element 1012.

The variable inductance element 1014 includes Terminal 1 (seventh terminal) connected to the input end 1071 and Terminal 2 (eighth terminal) connected to Terminal 1 of the variable inductance element 1013.

The variable capacitance element 1015 includes Terminal 1 (ninth terminal) connected to Terminal 1 of the variable inductance element 1011 and Terminal 2 (tenth terminal) grounded. The variable capacitance element 1016 includes Terminal 1 (eleventh terminal) connected to Terminal 2 of the variable inductance element 1011 and Terminal 2 (twelfth terminal) grounded.

The variable capacitance element 1017 includes Terminal 1 (thirteenth terminal) connected to Terminal 1 of the variable inductance element 1013 and Terminal 2 (fourteenth terminal) grounded. The variable capacitance element 1018 includes Terminal 1 (fifteenth terminal) connected to Terminal 2 of the variable inductance element 1013 and Terminal 2 (sixteenth terminal) grounded.

The splitter 101 is configured to split the signal RF1 into the signal RF2, which has a power level (first power level), and the signal RF3, which has a different power level (second power level), as a function of the values of inductance of the variable inductance elements 1011, 1012, 1013, and 1014 and the values of capacitance of the variable capacitance elements 1015, 1016, 1017, and 1018. The signal RF2 and the signal RF3 have phases that differ from each other, for example, by approximately 90°. A difference of approximately 90° in the present invention ranges from 45° to 120°.

In other words, the value of impedance of the splitter 101 varies depending on the values of inductance of the variable inductance elements 1011, 1012, 1013, and 1014 and the values of capacitance of the variable capacitance elements 1015, 1016, 1017, and 1018. The splitting into the signal RF2 and the signal RF3 is performed by the splitter 101 based on the value of impedance. The number of elements included in the splitter 101 and the connections between the elements are not limited to those described in this example.

For example, the splitter 101 is configured to output the signal RF2 and the signal RF3 so that the power level of the signal RF2 equals the power level of the signal RF3. Other examples of splitting will be described below.

The carrier amplifier 102 includes the input connected to the splitter 101 and the output connected to the combiner 104. A supply voltage Vcc1 is provided to the carrier amplifier 102. The carrier amplifier 102 is configured to amplify the signal RF2 from the splitter 101 and output a signal RF4 (fourth signal).

The peaking amplifier 103 includes the input connected to the splitter 101 and the output connected to the combiner 104. A supply voltage Vcc1 is provided to the peaking amplifier 103. The peaking amplifier 103 is configured to amplify the signal RF3 from the splitter 101 and output a signal RF5 (fifth signal).

Examples of the carrier amplifier 102 and the peaking amplifier 103 include a bipolar transistor such as a heterojunction bipolar transistor (HBT) and a field effect transistor such as a metal-oxide-semiconductor field effect transistor (MOSFET).

In the exemplary embodiment, for example, the carrier amplifier 102 is configured to be supplied with bias current or voltage so as to operate in a Class AB mode. The peaking amplifier 103 is configured to be supplied with bias current or voltage so as to operate in a Class C mode at this time. The peaking amplifier 103 may be configured to operate in a mode such as a Class AB or B mode.

The carrier amplifier 102 is configured to amplify the signal RF2 regardless of the power level of the signal RF2. The peaking amplifier 103 is configured to amplify the signal RF3 when the signal RF3 has a power level equal to or higher than a predetermined power level.

The power level at which the peaking amplifier 103 operates is set to a power level lower by a predetermined power level than the maximum power level that the power amplification circuit 10 is configured to output. The difference between the maximum power level and the power level at which the peaking amplifier 103 operates is referred to as the amount of back-off.

For example, in the case of the amount of back-off approximately equal to 6 dB, the splitter 101 performs splitting so that the power level of the signal RF2 equals the power level of the signal RF3, and thereby the required amount of back-off is obtained. More specifically, the splitter 101 performs splitting so that each of the signals RF2 and RF3 has a lower power level than the signal RF1 by approximately 3 dB.

The combiner 104 includes a phase shifter 1041 and a node 1042. The combiner 104 is configured to combine the signal RF4 and the signal RF5.

The phase shifter 1041 includes Terminal 1 connected to the carrier amplifier 102 and Terminal 2 connected to the node 1042. The phase shifter 1041 is an element configured to convert the impedance seen at the output of the carrier amplifier 102 looking into the node 1042. Examples of the phase shifter 1041 include a λ/4 line. The impedance conversion changes the phase of the signal RF4.

The node 1042 is the connection point at which the line from the output of the carrier amplifier 102 and the line from the output of the peaking amplifier 103 are connected.

For example, if the signal RF2 has a phase advance of approximately 90° relative to the signal RF3, the phase shifter 1041 delays the phase of the signal RF4 by approximately 90°. In this way, the signal RF4 and the signal RF5 are set in phase. The signal RF4 and the signal RF5 are combined in phase at the node 1042, which is the connection point of the lines, and become a signal RF6.

The phase shifter 105 is an impedance conversion element including Terminal 1 connected to the node 1042 and Terminal 2 connected to an output end 1072. Examples of the phase shifter 105 include a λ/4 line. The phase shifter 105 is configured to control the impedance between the node 1042 and the output end 1072.

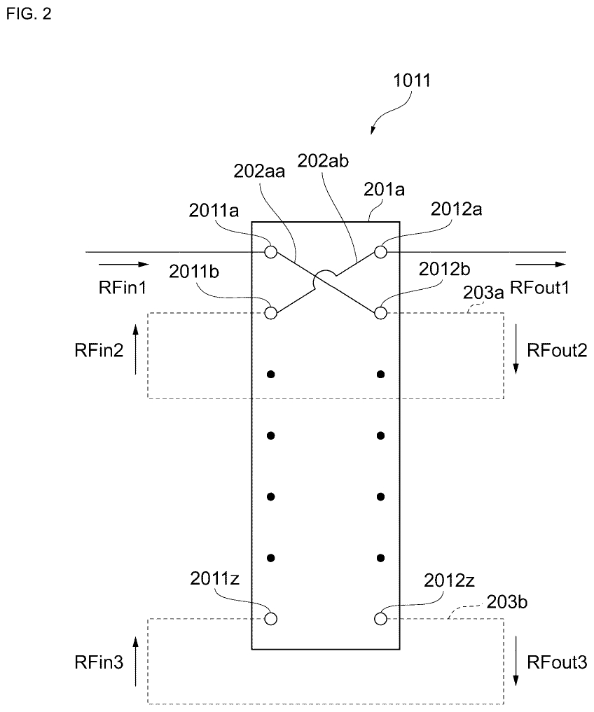

With reference to FIG. 2, the configurations of the variable inductance elements 1011, 1012, 1013, and 1014 will be described. The variable inductance element 1011 will be described herein as an example. Each of the variable inductance elements 1012 to 1014 also has a configuration similar to that of the variable inductance element 1011.

FIG. 2 is a circuit diagram of the variable inductance element 1011. The variable inductance element 1011 includes a switch 201a and onboard circuits 203a and 203b. The switch 201a includes multiple input terminals and multiple output terminals.

FIG. 2 presents input terminals 2011a (first input terminal), 2011b (second input terminal), and 2011z of the multiple input terminals. FIG. 2 also presents output terminals 2012a (first output terminal), 2012b (second output terminal), and 2012z of the multiple output terminals. Each of the input terminals 2011a, 2011b, and 2011z may be referred to as the input terminal 2011 below. Each of the output terminals 2012a, 2012b, and 2012z may be referred to as the output terminal 2012.

The number of the input terminals 2011 may be two, four, or more than four. The number of the output terminals 2012 may be two, four, or more than four. The number of the input terminals 2011 may be equal to or different from the number of the output terminals 2012.

A signal is input to the input terminal 2011 from the outside of the switch 201a. A signal is output from the output terminal 2012 to the outside of the switch 201a. The input terminals included in the switch may include a terminal from which a signal is output to the outside of the switch 201a. The output terminals included in the switch may include a terminal to which a signal is input from the outside of the switch 201a.

The switch 201a is able to form one or more connection paths (referred to as internal connection paths hereinafter) each electrically connecting one of the multiple input terminals and one of the multiple output terminals in the switch 201a.

The switch 201a is configured to form a single internal connection path for one input terminal or one output terminal. In other words, one input terminal is not connected to multiple output terminals by using multiple internal connection paths, and multiple input terminals are not connected to one output terminal by using multiple internal connection paths in the switch 201a. The switch 201a does not have a function of such direct mapping.

In FIG. 2, internal connection paths 202aa and 202ab are formed in the switch 201a with the internal connection path 202aa electrically connecting the input terminal 2011a and the output terminal 2012b and the internal connection path 202ab electrically connecting the input terminal 2011b and the output terminal 2012a.

The switch 201a is formed by using, for example, a semiconductor device such as an FET, a transistor, or a diode. The switch 201a may also be formed by using a device such as a relay configured to change connections by mechanically closing or opening a contact.

An input signal RFin1 (first input signal) is input to the input terminal 2011a. An output signal RFout1 (first output signal) is output from the output terminal 2012a. One end of the variable inductance element 1011 is the input terminal 2011a and the other end is the output terminal 2012a.

An output signal RFout2 (second output signal) is output from the output terminal 2012b. An input signal RFin2 (second input signal) is input to the input terminal 2011b.

An output signal RFout3 is output from the output terminal 2012z. An input signal RFin3 is input to the input terminal 2011z.

The onboard circuits 203a and 203b (external circuits) are disposed outside the switch 201a. In the present embodiment, the onboard circuits 203a and 203b are each a circuit disposed on a printed circuit board (PCB) such as a glass board or an epoxy board. A board made of liquid crystal polymer or low temperature co-fire ceramic (LTTCC) may be used.

The onboard circuit 203a is configured to electrically connect the output terminal 2012b and the input terminal 2011b in such a manner that the output signal RFout2, which is output from the output terminal 2012b, is input to the input terminal 2011b as the input signal RFin2. The onboard circuit 203b is configured to electrically connect the output terminal 2012z and the input terminal 2011z in such a manner that the output signal RFout3, which is output from the output terminal 2012z, is input to the input terminal 2011z as the input signal RFin3.

For example, some or all of the wiring in each of the onboard circuits 203a and 203b is wound on a printed circuit board and configured to function as an inductor. Each of the onboard circuits 203a and 203b may be formed by a surface mount device (SMD), which is surface-mounted on a printed circuit board and configured to function as an inductor, and wiring electrically connecting the SMD and the switch 201a.

The variable inductance element 1011 is configured to switch between formed patterns of the internal connection paths and is thereby able to at least provide a circuit configured to transmit a signal to the onboard circuit 203a and a bypass circuit configured to directly transmit a signal from the input terminal 2011a to the output terminal 2012a. The number of connection patterns for circuits that can be formed in the variable inductance element 1011 can easily be increased, for example, with a connection between another output terminal and another onboard circuit, a connection between another input terminal and another onboard circuit, and a connection between another output terminal and another input terminal with another onboard circuit interposed therebetween.

In summary, the use of a single switch, which is the switch 201a, in the variable inductance element 1011 enables the variable inductance element 1011 to have various values of inductance. In this way, the variable inductance element 1011 not only can be downsized compared with a configuration including multiple inductors that are connected in series and each of which is connected in parallel with a switch but also can reduce variation in circuit characteristics due to variation in switch characteristics.

In addition, the variable inductance element 1011 is configured to switch between formed patterns of the internal connection paths and is thereby able to at least provide a circuit configured to transmit a signal to the onboard circuit 203a, a circuit configured to transmit a signal to the onboard circuit 203b, a circuit configured to transmit a signal to the onboard circuits 203a and 203b, and a bypass circuit configured to directly transmit a signal from the input terminal 2011a to the output terminal 2012a. In this way, for example, when the onboard circuits 203a and 203b each function as an inductor, the value of inductance of the variable inductance element 1011 can be controlled.

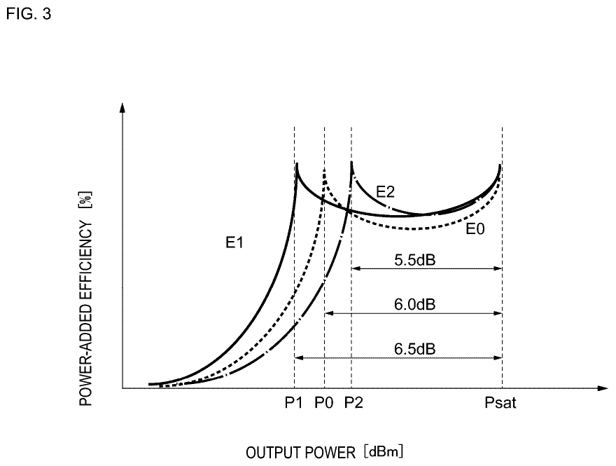

With reference to FIG. 3, the operation of the power amplification circuit 10 will be described. FIG. 3 is a graph illustrating the relationship between the output power [dBm] and the power-added efficiency [%] of the power amplification circuit 10. FIG. 3 presents graphs E0, E1, and E2 of the power-added efficiency of the power amplification circuit 10 for different values of inductance of the variable inductance elements 1011 to 1014 and different values of capacitance of the variable capacitance elements 1015 to 1018.

For example, the power amplification circuit 10 is configured to amplify the signal RF1 based on the power level of the signal RF1, which is received by the power amplification circuit 10. The power amplification circuit 10 is configured to perform power amplification based on the peak to average power ratio (PAPR) of the input signal, which is the signal RF1.

For example, for a PAPR of approximately 6.0 dB, the power amplification circuit 10 performs amplifying operation such that the amount of back-off becomes approximately equal to 6.0 dB. Specifically, the peaking amplifier 103 amplifies the signal RF3 when the output power is equal to or higher than P0, P0 being approximately 6.0 dB lower than the maximum output power Psat, at which the carrier amplifier 102 and the peaking amplifier 103 operate in a saturated state. In this condition, the power amplification circuit 10 operates at the peak efficiency when the output power is equal to P0.

In such a case, for example, the values of inductance of the variable inductance elements 1011 and 1013 are set to 5.29 nH, and the values of inductance of the variable inductance elements 1012 and 1014 are set to 7.09 nH. In addition, for example, the values of capacitance of the variable capacitance elements 1015 to 1018 are set to 8.36 pF. These values are set for the elements when the frequency is set to 1 GHz.

In this case, the values of capacitance and the values of inductance described above lead to splitting by the splitter 101 such that each of the signals RF2 and RF3 has a lower power level than the signal RF1 by approximately 3 dB. In this way, the amount of back-off approximately equal to 6.0 dB is obtained, and the power amplification circuit 10 can operate at the peak efficiency when the output power is equal to P0.

For a PAPR of approximately 6.5 dB, the peaking amplifier 103 amplifies the signal RF3 when the output power is equal to or more than P1, which is approximately 6.5 dB less than the maximum output power Psat. In this condition, the power amplification circuit 10 operates at the peak efficiency when the output power is equal to P1.

In such a case, for example, the values of inductance of the variable inductance elements 1011 and 1013 are set to 5.94 nH, and the values of inductance of the variable inductance elements 1012 and 1014 are set to 8.93 nH. In addition, for example, the values of capacitance of the variable capacitance elements 1015 to 1018 are set to 7.10 pF. These values are set for the elements when the frequency is set to 1 GHz.

In this case, the values of capacitance and the values of inductance described above lead to splitting by the splitter 101 such that the signal RF2 has a lower power level than the signal RF1 by approximately 2.5 dB and the signal RF3 has a lower power level than the signal RF1 by approximately 3.5 dB.

In other words, the splitter 101 allocates more power to the carrier amplifier 102 and less power to the peaking amplifier 103 than in the case of the amount of back-off approximately equal to 6.0 dB. Since the signal RF2 having a higher power level is received by the carrier amplifier 102, the output power P1, at which the carrier amplifier 102 becomes saturated, is less than the output power P0. In this way, more power is supplied to the carrier amplifier 102, and thereby the output power can be set to a value at which the power amplification circuit 10 operates at the peak efficiency.

For example, the PAPR of an input signal changes from approximately 6.0 dB to approximately 6.5 dB. At this time, the values of inductance of the variable inductance elements 1011 to 1014 and the values of capacitance of the variable capacitance elements 1015 to 1018 are controlled, and the power split ratio of the splitter 101 is adjusted, leading to efficient power amplification by the power amplification circuit 10.

For a PAPR of approximately 5.5 dB, the peaking amplifier 103 amplifies the signal RF3 when the output power is equal to or more than P2, which is approximately 5.5 dB less than the maximum output power Psat. In this condition, the power amplification circuit 10 operates at the peak efficiency when the output power is equal to P2.

In such a case, for example, the values of inductance of the variable inductance elements 1011 and 1013 are set to 5.63 nH, and the values of inductance of the variable inductance elements 1012 and 1014 are set to 7.96 nH. In addition, for example, the values of capacitance of the variable capacitance elements 1015 to 1018 are set to 7.69 pF. These values are set for the elements when the frequency is set to 1 GHz.

In this case, the values of capacitance and the values of inductance described above lead to splitting by the splitter 101 such that the signal RF2 has a lower power level than the signal RF1 by approximately 3.5 dB and the signal RF3 has a lower power level than the signal RF1 by approximately 2.5 dB.

In other words, the splitter 101 allocates less power to the carrier amplifier 102 and more power to the peaking amplifier 103 than in the case of the amount of back-off approximately equal to 6.0 dB. Since the signal RF2 having a lower power level is received by the carrier amplifier 102, the output power P2, at which the carrier amplifier 102 becomes saturated, is more than the output power P0. In this way, less power is supplied to the carrier amplifier 102, and thereby the output power can be set to a value at which the power amplification circuit 10 operates at the peak efficiency.

When the PAPR of an input signal changes from approximately 6.0 dB to approximately 5.5 dB, the power split ratio of the splitter 101 is also adjusted in a similar manner, leading to efficient power amplification by the power amplification circuit 10.

In summary, the power amplification circuit 10 can perform power amplification appropriate for the power level of an input signal.

A second exemplary embodiment will be described herein. In the second exemplary embodiment and later, features common to the first exemplary embodiment will not be described, and only different features will be described. In particular, similar operations and similar advantageous effects achievable by similar configurations will not individually be described in each of the exemplary embodiments.

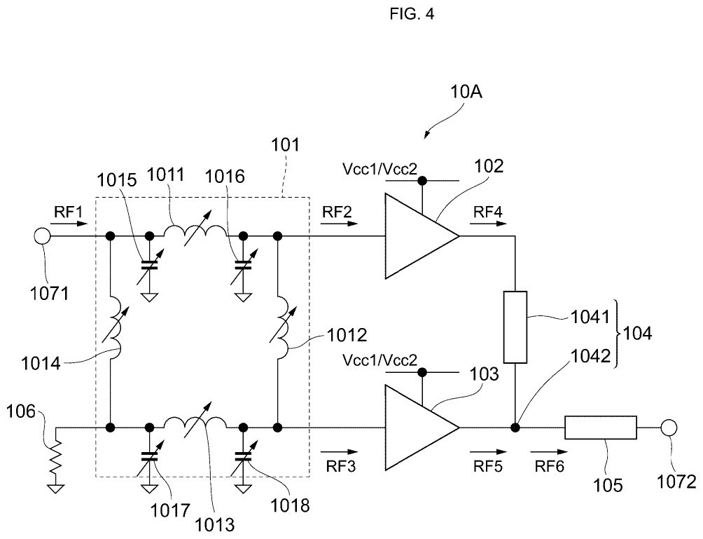

FIG. 4 is a circuit diagram of a power amplification circuit 10A according to the second exemplary embodiment. The power amplification circuit 10A differs from the power amplification circuit 10 in that the supply voltage provided to the carrier amplifier 102 and the peaking amplifier 103 is a supply voltage Vcc2 (second supply voltage) and that the supply voltage Vcc2 is lower than the supply voltage Vcc1 or the supply voltage Vcc1 (first supply voltage) in the power amplification circuit 10.

The power amplification circuit 10A can switch between operational states in response to the power level of an output signal, and the operational states include a high power mode (first amplification mode) and a low power mode (second amplification mode). The high power mode mentioned here differs from an operational state in which the peaking amplifier 103 operates in Doherty operation illustrated in FIG. 3. The high power mode and the low power mode differ from each other in the maximum value of the output power.

The power amplification circuit 10A is configured to switch between the operational states, for example, by changing supply voltages provided to the carrier amplifier 102 and the peaking amplifier 103. When the power amplification circuit 10A operates in the high power mode, the supply voltage Vcc1 is provided to the carrier amplifier 102 and the peaking amplifier 103. When the power amplification circuit 10A operates in the low power mode, the supply voltage Vcc2 is provided to the carrier amplifier 102 and the peaking amplifier 103.

The bias current or voltage provided to the carrier amplifier 102 is controlled so that the carrier amplifier 102 operates in a Class AB mode in the high power mode and the low power mode. The bias current or voltage provided to the peaking amplifier 103 is controlled so that the peaking amplifier 103 operates in a Class C mode in the high power mode and the low power mode.

Switching between the supply voltages is controlled, for example, by an external control circuit, which causes a device such as a switch to connect the carrier amplifier 102 and the peaking amplifier 103 to a power line providing the supply voltage Vcc1 or to a power line providing the supply voltage Vcc2.

When the switching between the high power mode and the low power mode is performed as in the power amplification circuit 10A, the power amplification circuit 10 preferably has a lower gain in the low power mode than in the high power mode.

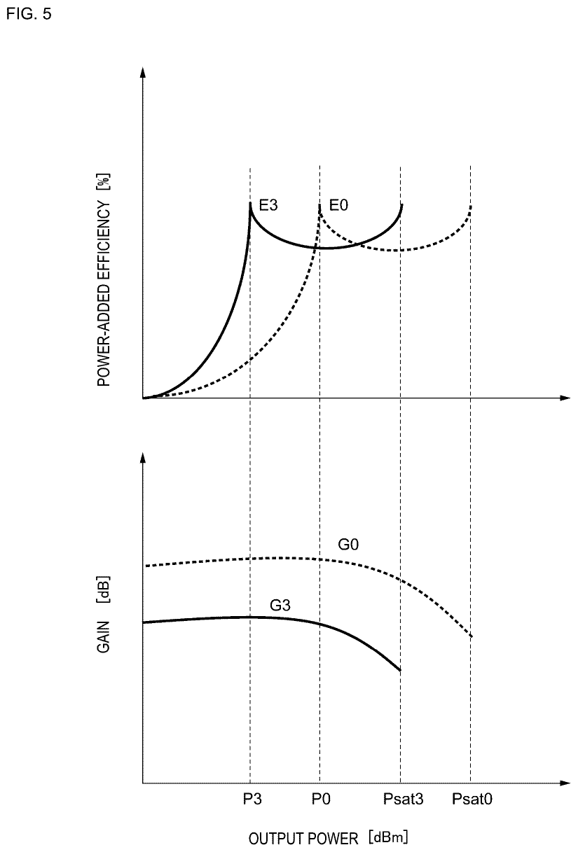

With reference to FIG. 5, the operation of the power amplification circuit 10 will be described. FIG. 5 is a graph illustrating the power-added efficiency [%] and the gain [dB] of the power amplification circuit 10 as a function of the output power [dBm]. In FIG. 5, the power-added efficiency E3 and the gain G3 in the low power mode are denoted by solid lines, and the power-added efficiency E0 and the gain G0 in the high power mode are denoted by dashed lines.

The gains G0 and G3 are each the gain along the path starting from the input end 1071, running through the carrier amplifier 102, and leading to the output end 1072 in the power amplification circuit 10A.

The graph of the power-added efficiency E0 in the high power mode appears similar to the graph for the power amplification circuit 10 according to the first exemplary embodiment, which is depicted in FIG. 3. The graph denoted by G0 represents the gain in this case.

In the low power mode, the splitter 101 performs splitting so that the signal RF2 has a lower power level than the signal RF1 by approximately (3+X) dB and the signal RF3 has a lower power level than the signal RF1 by approximately (3−X) dB. In short, the splitter 101 performs splitting so that the signal RF2 has a lower power level than the signal RF3.

The values of inductance of the variable inductance elements 1011 to 1014 and the values of capacitance of the variable capacitance elements 1015 to 1018 are appropriately controlled in the splitter 101 at this time. The graph denoted by G0 represents the gain in this case.

In FIG. 5, the power-added efficiency E0 and the power-added efficiency E3 are compared. The maximum output power Psat3 for the power-added efficiency E3 in the low power mode is less than the maximum output power Psat0 for the power-added efficiency E0 in the high power mode. This is because the supply voltage Vcc2 is lower than the supply voltage Vcc1.

Further, the power-added efficiency E3 peaks at the output power P3. The output power P3 is less than the output power P0, at which the power-added efficiency E0 peaks. This is because the splitter 101 allocates less power to the carrier amplifier 102 and more power to the peaking amplifier 103. Namely, the peaking amplifier 103 performs amplifying operation even when the signal RF1 has a lower power level since more power is supplied to the peaking amplifier 103.

In FIG. 5, the gain G0 and the gain G3 are compared. The gain G3, which is in the low power mode, is smaller than the gain G0, which is in the high power mode. This is because the splitter 101 allocates less power to the carrier amplifier 102 and more power to the peaking amplifier 103. Since the gains G0 and G3 are each the gain along the path starting from the input end 1071, running through the carrier amplifier 102, and leading to the output end 1072, the gain decreases as the power level allocated to the carrier amplifier 102 decreases. For example, when the power level of the signal RF2 is approximately (3+X) dB lower than the power level of the signal RF1, the gain is X dB lower than when the power level of the signal RF2 is approximately 3 dB lower than the power level of the signal RF1.

The power amplification circuit 10A is configured to have a lower gain in the low power mode than in the high power mode by the control of the split ratio between the signal RF2 and the signal RF3 in the splitter 101. In summary, the power amplification circuit 10A can perform power amplification appropriate for the operational state of the power amplification circuit 10A.

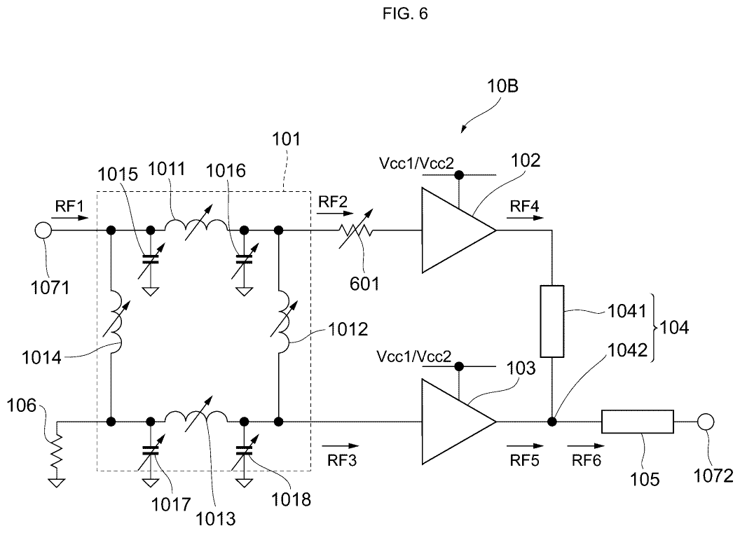

A third exemplary embodiment will be described. FIG. 6 is a circuit diagram of a power amplification circuit 10B according to the third exemplary embodiment. The operational states of the power amplification circuit 10B include a high power mode and a low power mode as included in the operational states of the power amplification circuit 10A.

The power amplification circuit 10B differs from the power amplification circuit 10A in that a variable attenuator 601 is disposed between the splitter 101 and the carrier amplifier 102.

The variable attenuator 601 includes at least one variable resistance element whose value of resistance can be controlled. The signal RF2 is provided to the carrier amplifier 102 after the power level is lowered by the variable attenuator 601. Namely, the power amplification circuit 10B has a still lower gain in the low power mode than the power amplification circuit 10A.

The power amplification circuit 10B is configured to have a lower gain in the low power mode than in the high power mode by causing the variable attenuator 601 to attenuate the signal RF2 in addition to the control of the split ratio. In summary, the power amplification circuit 10B can also perform power amplification appropriate for the operational state of the power amplification circuit 10B.

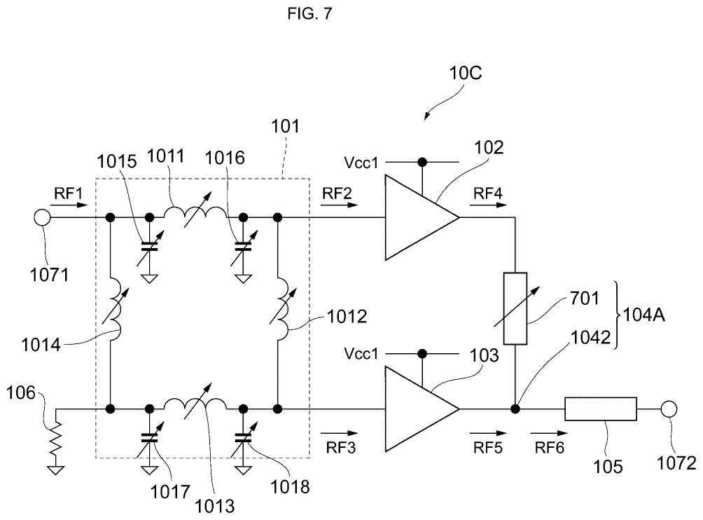

A fourth exemplary embodiment will be described. FIG. 7 is a circuit diagram of a power amplification circuit 10C according to the fourth exemplary embodiment. In the power amplification circuit 10C, a combiner 104A includes a variable impedance element 701. The power amplification circuit 10C differs from the power amplification circuit 10 in this regard.

The variable impedance element 701 has impedance that can be controlled as a function of the frequency of the signal RF1, which is received by the power amplification circuit 10C. The variable impedance element 701 is formed by, for example, a combination of components such as a variable inductance element, a variable capacitance element, and a variable resistance element. The impedance of the variable impedance element 701 is controlled as a function of the frequency of the signal RF1 so that the signal RF4 and the signal RF5 become in phase.

The values of inductance of the variable inductance elements 1011 to 1014 and the values of capacitance of the variable capacitance elements 1015 to 1018 are controlled as a function of the frequency of the signal RF1 in the power amplification circuit 10C.

In the following description, for example, it is assumed that the power levels of the signals RF2 and RF3 are approximately 3 dB lower than the power level of the signal RF1.

When the frequency of the signal RF1 is 1.0 GHz, for example, the values of inductance of the variable inductance elements 1011 and 1013 are set to 5.63 nH, and the values of inductance of the variable inductance elements 1012 and 1014 are set to 7.96 nH. In addition, for example, the values of capacitance of the variable capacitance elements 1015 to 1018 are set to 7.69 pF.

When the frequency of the signal RF1 is 1.5 GHz, for example, the values of inductance of the variable inductance elements 1011 and 1013 are set to 3.75 nH, and the values of inductance of the variable inductance elements 1012 and 1014 are set to 5.31 nH. In addition, for example, the values of capacitance of the variable capacitance elements 1015 to 1018 are set to 5.12 pF.

When the frequency of the signal RF1 is 2.0 GHz, for example, the values of inductance of the variable inductance elements 1011 and 1013 are set to 2.81 nH, and the values of inductance of the variable inductance elements 1012 and 1014 are set to 3.98 nH. In addition, for example, the values of capacitance of the variable capacitance elements 1015 to 1018 are set to 3.84 pF.

The values of inductance of the variable inductance elements 1011 to 1014, the values of capacitance of the variable capacitance elements 1015 to 1018, and the value of impedance of the variable impedance element 701 are controlled, and thereby the power amplification circuit 10C can perform power amplification appropriate for the frequency of the signal RF1. The split ratio between the signal RF2 and the signal RF3 in the power amplification circuit 10C may be variable as the split ratio in the power amplification circuit 10 is.

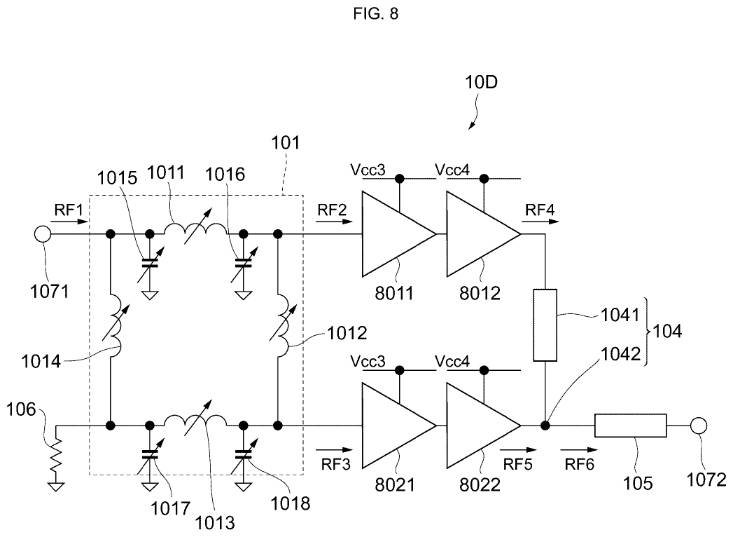

A fifth exemplary embodiment will be described. FIG. 8 is a circuit diagram of a power amplification circuit 10D according to the fifth exemplary embodiment. The power amplification circuit 10D includes amplifiers 8011, 8012, 8013, and 8014. The amplifiers 8011 and 8021 are provided with a supply voltage Vcc3. The amplifiers 8012 and 8022 are provided with a supply voltage Vcc4.

The amplifiers 8011 and 8012 are disposed to achieve multi-stage implementation of the carrier amplifier 102. The amplifiers 8021 and 8022 are disposed to achieve multi-stage implementation of the peaking amplifier 103.

The power amplification circuit 10D can also perform power amplification appropriate for the power level of an input signal as the power amplification circuit 10 does.

Some illustrative, or exemplary, embodiments of the present disclosure have been described. The power amplification circuit 10 includes the variable inductance elements 1011, 1012, 1013, and 1014, the variable capacitance elements 1015, 1016, 1017, and 1018, and the splitter 101 configured to split the signal RF1 into the signal RF2, which has the first power level, and the signal RF3, which has the second power level. The signal RF1 is split into the signal RF2 and the signal RF3 as a function of the values of inductance of the variable inductance elements 1011, 1012, 1013, and 1014 and the values of capacitance of the variable capacitance elements 1015, 1016, 1017, and 1018. The power amplification circuit 10 also includes the carrier amplifier 102, the peaking amplifier 103, and the combiner 104. The carrier amplifier 102 is connected to the splitter 101 and configured to amplify the signal RF2 and output the signal RF4, and the peaking amplifier 103 is connected to the splitter 101 and configured to amplify the signal RF3 and output the signal RF5 when the second power level is equal to or higher than the predetermined power level. The combiner 104 is configured to combine the signal RF4 and the signal RF5.

The splitter 101 is configured to split the signal RF1 into the signal RF2 and the signal RF3 as a function of the values of inductance of the variable inductance elements and the values of capacitance of the variable capacitance elements. When the first power level, which is the power level of the signal RF2, and the second power level, which is the power level of the signal RF3, differ from each other, the operation of the carrier amplifier 102, which is based on the first power level, and the operation of the peaking amplifier 103, which is based on the second power level, are controlled. In this way, the power amplification circuit 10 can perform power amplification appropriate for the condition of the signal RF1 on an occasion such as when the PAPR of the signal RF1 changes.

The splitter 101 is also configured to be able to control the values of inductance and the values of capacitance in such a manner that the second power level is lower than the first power level when the peak to average power ratio of the signal RF1 is larger than a predetermined value, and the splitter 101 is configured to be able to control the values of inductance and the values of capacitance in such a manner that the second power level is higher than the first power level when the peak to average power ratio of the signal RF1 is smaller than the predetermined value.

When the second power level decreases below the first power level, the output power at which the power amplification circuit 10 reaches the peak efficiency decreases. Thus, the amount of back-off can be increased with an increase in the peak to average power ratio. When the second power level decreases below the first power level, the output power at which the power amplification circuit 10 reaches the peak efficiency increases. Thus, the amount of back-off can be decreased with a decrease in the peak to average power ratio. In this way, the power amplification circuit 10 can perform power amplification appropriate for the condition of the signal RF1.

The operational states of the power amplification circuit 10A include the high power mode, in which the supply voltage Vcc1 is provided to the carrier amplifier 102 and the peaking amplifier 103, and the low power mode, in which the supply voltage Vcc2 is provided to the carrier amplifier 102 and the peaking amplifier 103, the supply voltage Vcc2 being lower than the supply voltage Vcc1, and the splitter 101 is configured to be able to control the values of inductance and the values of capacitance in such a manner that the second power level is higher than the first power level in the low power mode.

Thus, the first power level for the carrier amplifier 102 is lower than the second power level for the peaking amplifier 103 in the low power mode. Consequently, the power amplification circuit 10A can achieve a favorable gain in the low power mode. In summary, the power amplification circuit 10A can perform power amplification appropriate for the operational state of the power amplification circuit 10A.

The power amplification circuit 10B further includes the variable attenuator 601 disposed between the splitter 101 and the carrier amplifier 102. The first power level can further be lowered by using the variable attenuator 601. The power amplification circuit 10B can achieve a more favorable gain in the low power mode. In summary, the power amplification circuit 10B can perform power amplification appropriate for the operational state of the power amplification circuit 10B.

In the power amplification circuit 10C, the splitter 101 is configured to be able to control the values of inductance and the values of capacitance based on the frequency of the signal RF1, and the combiner 104A includes the variable impedance element 701 that is disposed between the carrier amplifier 102 and the peaking amplifier 103 and that is configured to be able to control the value of impedance based on the frequency.

The values of inductance of the variable inductance elements 1011 to 1014, the values of capacitance of the variable capacitance elements 1015 to 1018, and the value of impedance of the variable impedance element 701 are controlled, and thereby the power amplification circuit 10C can perform power amplification appropriate for the frequency of the signal RF1. In summary, the power amplification circuit 10B can perform power amplification appropriate for the condition of the signal RF1.

The variable inductance elements 1011, 1012, 1013, and 1014 each include the switch 201a including multiple input terminals and multiple output terminals, and the multiple input terminals include the input terminal 2011a, to which the input signal RFin1 is input, and the input terminal 2011b, to which the input signal Rfin2 is input. The multiple output terminals include the output terminal 2012a, from which the output signal Rfout1 is output, and the output terminal 2012b, from which the output signal Rfout2 is output. The switch 201a is able to form one or more internal connection paths electrically connecting one of the multiple input terminals and one of the multiple output terminals. The onboard circuit 203a is configured to electrically connect the output terminal 2012z and the input terminal 2011z in such a manner that the output signal Rfout2 that is output from the output terminal 2012b is input to the input terminal 2011b as the input signal Rfin. The onboard circuit 203a is disposed outside the switch 201a.

The use of a single switch in the variable inductance element 1011, which is the switch 201a, enables the variable inductance element 1011 to have various values of inductance. In this way, the variable inductance element 1011 not only can be downsized compared with a configuration including multiple inductors that are connected in series and each of which is connected in parallel with a switch but also can reduce variation in circuit characteristics due to variation in switch characteristics.

In addition, the variable inductance element 1011 is configured to switch between formed patterns of the internal connection paths and is thereby able to at least provide a circuit configured to transmit a signal to the onboard circuit 203a, a circuit configured to transmit a signal to the onboard circuit 203b, a circuit configured to transmit a signal to the onboard circuits 203a and 203b, and a bypass circuit configured to directly transmit a signal from the input terminal 2011a to the output terminal 2012a. In this way, for example, when the onboard circuits 203a and 203b each function as an inductor, the value of inductance of the variable inductance element 1011 can be controlled.

The power amplification circuit 10 further includes the input end 1071, and the splitter 101 includes the variable inductance element 1011, the variable capacitance element 1015, and the variable capacitance element 1016. The variable inductance element 1011 includes one end connected to the input end 1071 and the other end connected to the carrier amplifier 102. The variable capacitance element 1015 includes one end connected to the one end of the variable inductance element 1011 and the other end grounded. The variable capacitance element 1016 includes one end connected to the other end of the variable inductance element 1011 and the other end grounded.

The power amplification circuit 10 includes the variable inductance element 1012, the variable inductance element 1013, the variable capacitance element 1017, the variable capacitance element 1018, and the variable inductance element 1014. The variable inductance element 1012 includes Terminal 1 connected to Terminal 2 of the variable inductance element 1011 and Terminal 2 connected to the peaking amplifier 103. The variable inductance element 1013 includes Terminal 1 grounded and Terminal 2 connected to Terminal 2 of the variable inductance element 1012. The variable capacitance element 1017 includes Terminal 1 connected to Terminal 1 of the variable inductance element 1013 and Terminal 2 grounded. The variable capacitance element 1018 includes Terminal 1 connected to Terminal 2 of the variable inductance element 1013 and Terminal 2 grounded. The variable inductance element 1014 includes Terminal 1 connected to the input end 1071 and Terminal 2 connected to Terminal 1 of the variable inductance element 1013.

In this way, the power amplification circuit 10 can perform power amplification appropriate for the condition of the signal RF1.

The exemplary embodiments described above are provided for easy understanding of the present disclosure and are not intended to limit the present disclosure. Modifications and improvements can be made to the present disclosure without departing from the spirit thereof, and the equivalents thereof are also encompassed by the present disclosure. That is, these exemplary embodiments may be appropriately modified in design by those skilled in the art, and such modifications also fall within the scope of the present disclosure as long as the modifications include the features of the present disclosure. For example, the elements included in the exemplary embodiments and parameters such as arrangement, materials, conditions, shapes, sizes of the elements are not limited to those described in the examples but can be modified appropriately. It is also to be understood that the exemplary embodiments have been described for illustrative purposes and that partial substitutions or combinations of configurations illustrated in different exemplary embodiments can be made, and the scope of the present disclosure also encompasses such substitutions or combinations as long as the substitutions or combinations include the features of the present disclosure.

### REFERENCE SIGNS LIST

10, 10A, 10B, 10C, 10D power amplification circuit
101 splitter
102 carrier amplifier
103 peaking amplifier
104, 104A combiner
105 phase shifter
1011, 1012, 1013, 1014 variable inductance element
1015, 1016, 1017, 1018 variable capacitance element

1. A power amplification circuit comprising:
a splitter that includes at least one variable inductance element and at least one variable capacitance element and that is configured to split a first signal into a second signal having a first power level and a third signal having a second power level based on a value of inductance of each of the at least one variable inductance element and a value of capacitance of each of the at least one variable capacitance element;
a first amplifier that is connected to the splitter and that is configured to amplify the second signal and output a fourth signal;
a second amplifier that is connected to the splitter and that is configured to amplify the third signal and output a fifth signal when the second power level is greater than or equal to a predetermined power level; and
a combiner configured to combine the fourth signal and the fifth signal.

2. The power amplification circuit according to claim 1, wherein the splitter is configured to
control the at least one value of inductance and the at least one value of capacitance to cause the second power level to be lower than the first power level when a peak to average power ratio of the first signal is larger than a predetermined value, and
control the at least one value of inductance and the at least one value of capacitance to cause the second power level to be higher than the first power level when the peak to average power ratio of the first signal is smaller than the predetermined value.

3. The power amplification circuit according to claim 1,
wherein operational states of the power amplification circuit include a first amplification mode in which a first supply voltage is provided to the first amplifier and the second amplifier and a second amplification mode in which a second supply voltage lower than the first supply voltage is provided to the first amplifier and the second amplifier, and
the splitter is configured to control the at least one value of inductance and the at least one value of capacitance to cause the second power level to be higher than the first power level in the second amplification mode.

4. The power amplification circuit according to claim 3, further comprising:
a variable attenuator disposed between the splitter and the first amplifier.

5. The power amplification circuit according to claim 1,
wherein the splitter is configured to control the at least one value of inductance and the at least one value of capacitance based on a frequency of the first signal, and
the combiner includes a variable impedance element that is disposed between the first amplifier and the second amplifier and that is configured to control a value of impedance based on the frequency.

6. The power amplification circuit according to claim 1,
wherein the at least one variable inductance element each includes
a switch including a plurality of input terminals and a plurality of output terminals,
the plurality of input terminals include a first input terminal to which a first input signal is input and a second input terminal to which a second input signal is input,
the plurality of output terminals include a first output terminal from which a first output signal is output and a second output terminal from which a second output signal is output,
the switch is configured to form one or more internal connection paths each electrically connecting one of the plurality of input terminals and one of the plurality of output terminals, and
the at least one variable inductance element each further includes an external circuit that is disposed outside the switch and that is configured to electrically connect the second output terminal and the second input terminal to cause the second output signal, which is output from the second output terminal, to be input to the second input terminal as the second input signal.

7. The power amplification circuit according to claim 1, further comprising:
an input end,
wherein the splitter includes
a first variable inductance element including a first terminal connected to the input end and a second terminal connected to the first amplifier,
a first variable capacitance element including a third terminal connected to the first terminal and a fourth terminal grounded,
a second variable capacitance element including a fifth terminal connected to the second terminal and a sixth terminal grounded,
a second variable inductance element including a seventh terminal connected to the second terminal and an eighth terminal connected to the second amplifier,
a third variable inductance element including a ninth terminal grounded and a tenth terminal connected to the eighth terminal,
a third variable capacitance element including an eleventh terminal connected to the ninth terminal and a twelfth terminal grounded,
a fourth variable capacitance element including a thirteenth terminal connected to the tenth terminal and a fourteenth terminal grounded, and
a fourth variable inductance element including a fifteenth terminal connected to the input end and a sixteenth terminal connected to the ninth terminal.

8. The power amplification circuit according to claim 1, wherein the at least one variable capacitance element includes a digitally tunable capacitor.

9. The power amplification circuit according to claim 6, wherein the external circuit is mounted on a board made of liquid crystal polymer or low temperature co-fire ceramic (LTTCC).

10. The power amplification circuit according to claim 6, wherein the switch includes a field effect transistor (FET).

11. The power amplification circuit according to claim 6, wherein the switch includes a relay.

12. The power amplification circuit according to claim 2, wherein the predetermined value is 6.0 dB.

13. The power amplification circuit according to claim 1, wherein the first amplifier is configured to operate in Class AB mode.

14. The power amplification circuit according to claim 1, wherein the second amplified is configured to operate in Class C mode.

15. The power amplification circuit according to claim 2, wherein operational states of the power amplification circuit include a first amplification mode in which a first supply voltage is provided to the first amplifier and the second amplifier and a second amplification mode in which a second supply voltage lower than the first supply voltage is provided to the first amplifier and the second amplifier.

16. The power amplification circuit according to claim 15, wherein the splitter is configured to control the at least one value of inductance and the at least one value of capacitance to cause the second power level to be higher than the first power level in the second amplification mode.

17. The power amplification circuit according to claim 2, wherein the splitter is configured to control the at least one value of inductance and the at least one value of capacitance based on a frequency of the first signal, and
the combiner includes a variable impedance element that is disposed between the first amplifier and the second amplifier and that is configured to control a value of impedance based on the frequency.

18. The power amplification circuit according to claim 3, wherein the splitter is configured to control the at least one value of inductance and the at least one value of capacitance based on a frequency of the first signal, and
the combiner includes a variable impedance element that is disposed between the first amplifier and the second amplifier and that is configured to control a value of impedance based on the frequency.

19. The power amplification circuit according to claim 4, wherein the splitter is configured to control the at least one value of inductance and the at least one value of capacitance based on a frequency of the first signal, and
the combiner includes a variable impedance element that is disposed between the first amplifier and the second amplifier and that is configured to control a value of impedance based on the frequency.

20. The power amplification circuit according to claim 1, wherein the first amplifier is a carrier amplifier and the second amplifier is a peaking amplifier.
